(19) United States
(12) Patent Application Publication
(10) Pub. No.: US 2011/0129617 A1
(43) Pub. Date: Jun. 2, 2011

(54) Plasma system and method of producing a functional coating

(76) Inventors: Stefan Grosse, Gerlingen (DE); Sascha Henke, Weil der Stadt (DE); Susanne Spindler, Stuttgart (DE)

(21) Appl. No.: 10/240,477

(22) PCT Filed: Dec. 5, 2001
(86) PCT No.: PCT/DE01/04564

§ 371 Date: Feb. 9, 2011

(30) Foreign Application Priority Data
Feb. 2, 2001 (DE) 101 04 614.6-33

(51) Int. Cl. C23C 16/50; C23C 16/455; C23C 16/458; C23C 16/52

(52) U.S. Cl. 427/578; 118/723 R; 427/569

(57) ABSTRACT

A plasma system has at least one inductively coupled high-frequency plasma jet source having a burner body delimiting a plasma generating space having an outlet orifice for the plasma jet, a coil surrounding the plasma generating space in some areas, an inlet for supplying a gas and/or a precursor material into the plasma generating space and a high-frequency generator which is connected to the coil for igniting the plasma and for injecting an electric power into the plasma. The plasma jet source has an electric component using which the intensity of the plasma jet is variable periodically over time. In addition, a method of producing the functional coating on a substrate by using this plasma system is described.

### FIELD OF THE INVENTION

The present invention relates to a plasma system having a high-frequency inductively coupled plasma jet source and a method of producing a functional coating on a substrate.

### BACKGROUND INFORMATION

Applying functional coatings to substrates is a widely used method of imparting desired properties to the surfaces of workpieces and/or components. A conventional method of producing such functional layers is by plasma coating in a medium-high or high vacuum, which requires complex evacuation techniques and yields relatively low coating rates. Therefore, this method is time-intensive and expensive.

Thermal plasmas in particular which allow high coating rates in the range of mm/h to be achieved are suitable for coating substrates in the atmospheric and subatmospheric pressure range. Of the thermal plasma sources, the high-frequency inductively coupled plasma jet source (HF-ICP jet source) is especially promising, such as that known from E. Pfender and C. H. Chang “Plasma Spray Jets and Plasma Particulate Interaction: Modeling and Experiments,” Convention Volume of the 6^{th} Workshop on Plasma Technology, Technical University of Illmenau, 1998. Furthermore, German Published Patent Application No. 199 58 474 has proposed a method of producing functional layers by using such a plasma jet source.

The advantages of the HF-ICP jet source include the range of operating pressures in the source, usually extending from 50 mbar to 1 bar or more, and also the great variety of materials that may be used and deposited with such a plasma jet source. In particular, due to the fact that the starting materials are introduced axially into the very hot plasma jet, hard substances having a very high melting point may also be used. Another advantage of the HF-ICP jet source is that it works without electrodes, i.e., contamination of the layers produced by the jet source electrode material are prevented.

One disadvantage of the known HF-ICP jet sources and plasma systems using such plasma jet sources is the high temperatures in the plasma jet of several thousand degrees Celsius to which the substrate that is to be coated is also exposed. To this extent, the choice of usable substrates is considerably restricted.

### SUMMARY OF THE INVENTION

An object of the present invention is to provide a plasma system having an HF inductively coupled plasma jet source and a method implementable therewith for producing a functional coating on a substrate, so that the thermal load on the substrate in producing the functional coating is greatly reduced in comparison with the related art.

The plasma system according to the present invention and the method according to the present invention for producing a functional coating on a substrate by varying the plasma intensity over time have the advantage over the related art that the temperature to which the substrate is exposed may be reduced to less than half in comparison with the related art.

It is also advantageous that using the plasma system according to the present invention, the advantages of a high-rate deposition method taking place in the atmospheric or near-atmospheric pressure range are combined with a reduction in substrate temperature and a change in the chemical processes in the plasma thus produced.

It is advantageous in particular that the method according to the present invention is not a high-vacuum method, so that complex equipment for producing such a high vacuum is not necessary.

It is also advantageous that the method according to the present invention may also be used with virtually all industrially relevant substrate materials such as steel and, as the case may be, also polymers, and at the same time a wide selection of materials and/or compositions of the coating to be produced, e.g., including insulating materials such as ceramics or sintered metals, is also available.

In addition, due to the periodic change in intensity of the plasma jet, preferably to such an extent that the plasma jet is extinguished between intensity peaks, there is regularly a chemical and/or physical disequilibrium state in the plasma jet, which permits promising approaches for production of previously unknown layer systems, e.g., ceramic layers or layer systems.

In particular, the aforementioned disequilibrium states, which occur mainly on igniting and extinguishing the plasma, constitute a considerable portion of the total time during which the plasma jet acts on the substrate, given suitable pulsation of the plasma jet over time, so that chemical processes taking place in these disequilibrium states become a dominant factor for the entire deposition of functional coatings using such a plasma system and/or plasma jet source.

It is thus particularly advantageous if, in addition to a plasma jet whose intensity varies periodically, the substrate being coated is situated on a substrate electrode which receives a voltage which is in phase opposition or is varied, preferably pulsed, over time in correlation with the change in intensity of the plasma jet.

Another advantageous embodiment of the present invention provides for the supply of gas and/or precursor material to the plasma, i.e., the plasma jet, to be correlated in time, in particular synchronized, with the varying intensity of the plasma jet.

Finally, it is advantageous if, at least temporarily during the production of the functional layer, the greatest possible pressure gradient is produced between the inside of the chamber and the plasma generating space, causing an acceleration of particles contained in the plasma jet onto the substrate. In this way, even deeper cavities in the surface of the substrate are better reached by the plasma and there is improved adhesion of the functional layer to the substrate.

### BRIEF DESCRIPTION OF THE DRAWINGS

FIG. 1 shows a first embodiment of a plasma jet source in a sectional view.

FIG. 2 shows the periodic characteristic of the voltage across the plasma jet source over time.

FIGS. 3a through 3h show the plasma jet, whose intensity varies as a function of time.

FIG. 4 shows an exemplary embodiment of a plasma system having a plasma jet source.

FIG. 5 shows a second exemplary embodiment of a plasma system having a plasma jet source.

FIG. 6 shows a plasma jet exiting from the plasma jet source according to FIG. 4.

### DETAILED DESCRIPTION

The present invention is based first on a plasma jet source 5, which is known fundamentally from E. Pfender and C. H. Chang, “Plasma Spray Jets and Plasma Particulate Interaction: Modeling and Experiments,” Convention Volume of the 6^{th} Workshop on Plasma Technology, Technical University of Illmenau, 1998, or German Published Patent Application No. 199 58 474.

This plasma jet source 5 has a pot-shaped burner body 25 having a rear injector as an inlet 10 for supplying an injector gas 11. In addition, a first cylindrical sleeve 14 and a second cylindrical sleeve 15 are provided, a central gas 12 being supplied to the interior of first sleeve 14 through a suitable first inlet (not shown) and an enveloping gas 13 being supplied to the interior of second sleeve 15 through a suitable second inlet (not shown).

Burner body 25 also has an outlet orifice 26 in the form of a circle, for example, having a diameter of 1 cm to 10 cm, for example, in particular 3 cm on its side facing away from inlet 10, this opening being provided with an orifice restrictor 22 shaped according to the shape of plasma jet 21 to be produced. In addition, a water-cooled copper coil 17 is integrated into burner body 25 in the vicinity of outlet orifice 26 and is electrically connected to an HF generator 16.

When injector gas 11, central gas 12 and enveloping gas 13 are supplied, an electric power of 500 W to 50 kW, in particular 1 kW to 10 kW, is injected into the interior of burner body 25 at a high frequency of 0.5 MHz to 20 MHz, in particular 0.5 to 4 MHz, via coil 17 and HF generator 16, so that a plasma 21 of reactive particles emerging from outlet orifice 26 of burner body 25 in the form of a plasma jet 20 may be ignited and sustained in a plasma generating space 27. This plasma jet 20 then continues to act on a substrate 19, e.g., a piece of steel situated on a substrate carrier or a substrate electrode 18, situated opposite outlet orifice 26, e.g., at a distance of 5 cm to 50 cm.

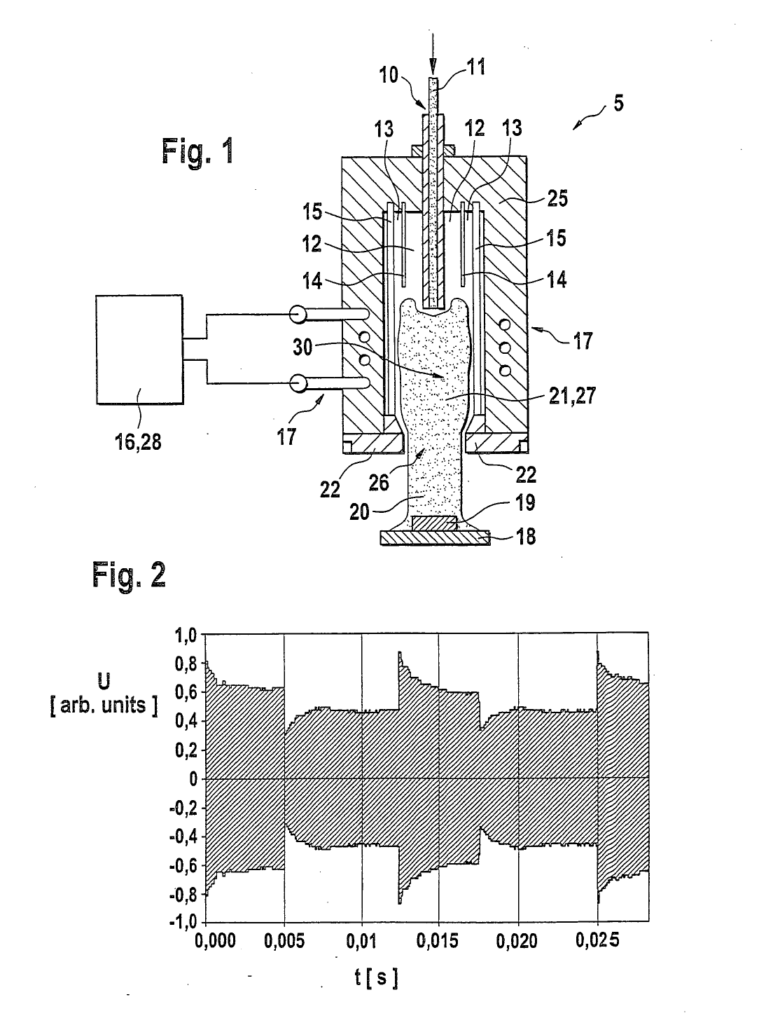

FIG. 1 also shows that, additionally in comparison with the related art, an electric component 28 is integrated into HF generator 16, for periodically varying the electric power delivered by HF generator 16 to coil 17, so that the intensity of the plasma jet thus produced is also varied periodically in this way.

Injector gas 11 introduced into burner body 25 through inlet 10, i.e., the injector is, for example, a precursor material for producing a functional coating on substrate 19. For example, a gas which reacts with injector gas 11 is suitable as central gas 12, which is optionally added. Enveloping gas 13, preferably argon, protects the walls of burner body 25 and also causes plasma 21 which is produced to be blown as a jet out of plasma jet source 5 through outlet orifice 26, so that it acts as a bundled or guided plasma jet 20 on substrate 19. To do so, enveloping gas 13 is introduced at a gas flow rate of 5000 sccm to 100,000 sccm (standard cubic centimeters per minute), preferably 20,000 sccm to 70,000 sccm.

The periodic variation in intensity of plasma jet 20 using electronic component 28, which may also be connected as a separate component between coil 17 and HF generator 16, takes place at a frequency of 1 Hz to 10 kHz, in particular 50 Hz to 1 kHz, between an adjustable upper limit and an adjustable lower limit of intensity. The lower limit is preferably set at zero, so that plasma jet 20 is periodically extinguished for a predefinable period of time. As an alternative, however, it is likewise possible to provide for the intensity of plasma jet 20 to be varied between the two limits given above in virtually any desired form, e.g., without plasma 21 being extinguished in the meantime. In particular, the intensity of plasma jet 20 may be varied in a rectangular, sinusoidal, sawtooth, rectangular or triangular form, optionally with a suitable offset, with respect to the resulting envelope.

For additional known details regarding the design of plasma jet source 5, as well as the methods performed with it for producing functional layers, reference is made to German Published Patent Application No. 199 58 474.

FIG. 2 illustrates how the intensity of plasma jet 20 varies as a function of time when electric component 28 controls the HF generator, i.e., suitably varies the supply of electric power to coil 17. HF voltage U applied to coil 17 is plotted on the ordinate in FIG. 2, its absolute value and the shape of the envelope being approximately proportional to the intensity of plasma jet 20.

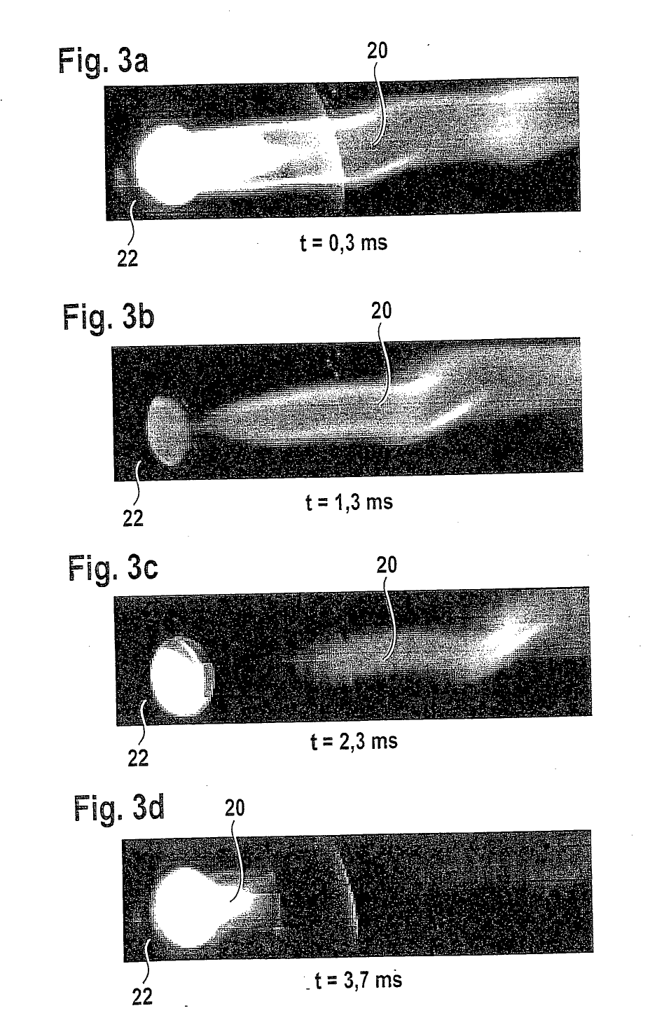

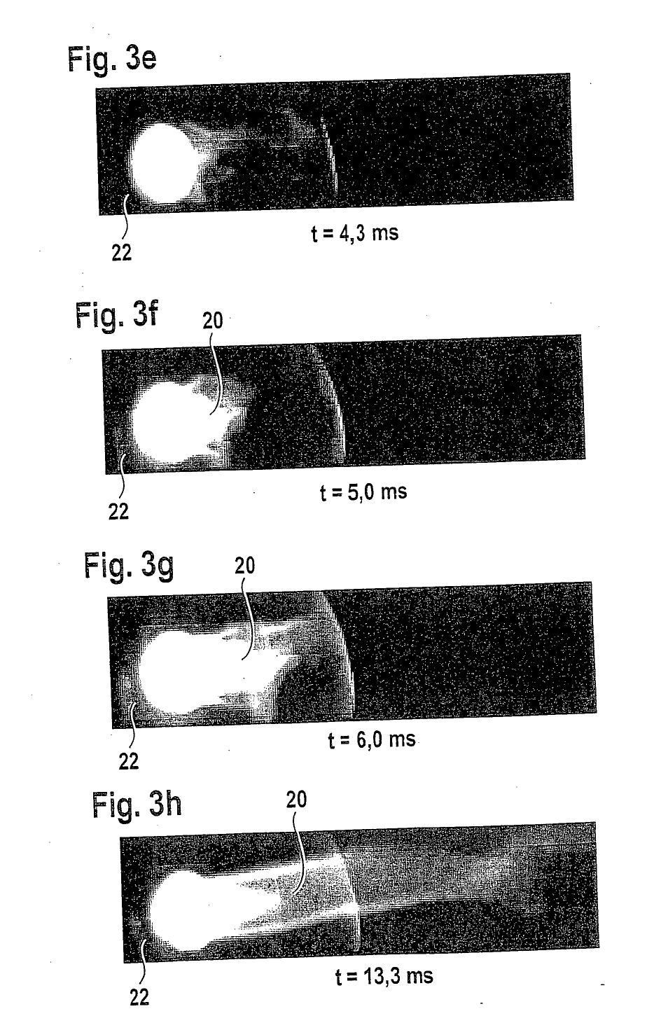

The intensity of plasma jet 20 from plasma jet source 5 and emerging from outlet orifice 26 of burner body 25 is explained with the help of FIGS. 3a through 3h for various times t between t=0.3 ms and t=13.3 ms. Plasma jet 20 emerges from outlet orifice 26 initially with a high intensity at time t=0 according to FIG. 3a; then this intensity diminishes significantly according to FIG. 3b, so that plasma jet 20 is completely extinguished shortly thereafter. Next, plasma jet 20 is reignited according to FIGS. 3c through 3e, swinging back shortly before expanding continuously according to FIGS. 3f through 3h, so that after approx. 13.3 ms it has almost reached the starting state according to FIG. 3a again. The pulsing of plasma jet 20 according to FIGS. 3a through 3h is induced by a change in the HF electric power injected into coil 17. FIGS. 3a through 3h show in particular that plasma jet 20 emerges from plasma jet source 5 with little divergence as a free and largely bundled plasma jet 20.

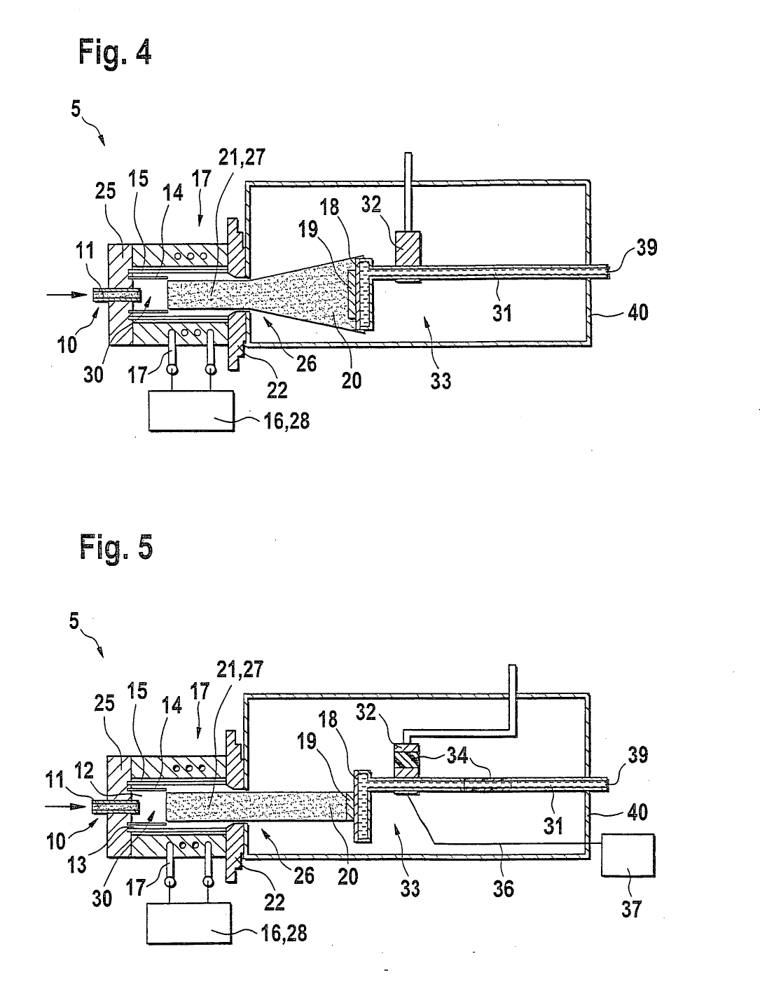

FIG. 4 illustrates a plasma system having a conventional chamber 40 in which substrate 19 is situated on a substrate carrier 18 opposite outlet orifice 26 of plasma jet source 5, so that plasma jet 20 passes through outlet orifice 26 and enters into chamber 40, where it is able to act on substrate 19. In particular, FIG. 4 shows that substrate carrier 18 is secured in chamber 40 with the help of a mount 32 and is coolable with cooling water 39 through a cooling water inlet 31.

According to FIG. 4, a first pressure p₁ between 10 mbar and 2 bar, in particular between 50 mbar and 1 bar, prevails in the interior of plasma jet source 5, i.e., in a first pressure area 30, and a second pressure p₂, which is a function of the size of outlet orifice 26 and the amount of enveloping gas 13 or injector gas 10 as well as the efficiency of the pumps connected to chamber 40, prevails in the interior of chamber 40, i.e., in a second pressure area 33. This pressure p₂ is preferably much lower than pressure p₁ due to a appropriately high pumping power, i.e., it is less than 100 mbar, for example, in particular less than 10 mbar. In addition, argon is used as enveloping gas 13 in FIG. 4 and is introduced into plasma jet source 5 at a gas flow rate of 40,000 sccm td 60,000 sccm.

In particular, due to the fact that according to FIG. 4, plasma jet source 5, i.e., the production of plasma 21 is spatially separated from the production of the functional coating on substrate 19, it is possible to use plasma jet 20 in chamber 40 at a pressure of 1 mbar to 10 mbar, for example, as a result of which plasma jet 20 is greatly accelerated and expands at the same time on emerging from plasma jet source 5, in the interior of which a much higher pressure of 500 mbar, for example, prevails. This is indicated schematically in FIG. 4 by plasma jet 20, which widens on emerging from outlet orifice 26.

Such an expanded and accelerated plasma jet 20 in which the reactive particles present in the plasma jet may easily reach the velocity of sound or even supersonic velocity is capable of penetrating into deep cavities present on substrate 19. In addition, such an expansion of plasma jet 20 results in sudden cooling of plasma 21, which in turn further lowers the thermal load on substrate 19 and also yields chemical advantages with regard to an increase in plasma coating rate and an increase in the quality of the coating thus produced on the substrate.

In particular, the spatial separation of the processes in chamber 40 from plasma jet source 5 guarantees that plasma jet 20 may also be used in chamber 40 in a medium-high vacuum of 1 mbar without any change in the plasma mode, which is determined by plasma jet source 5.

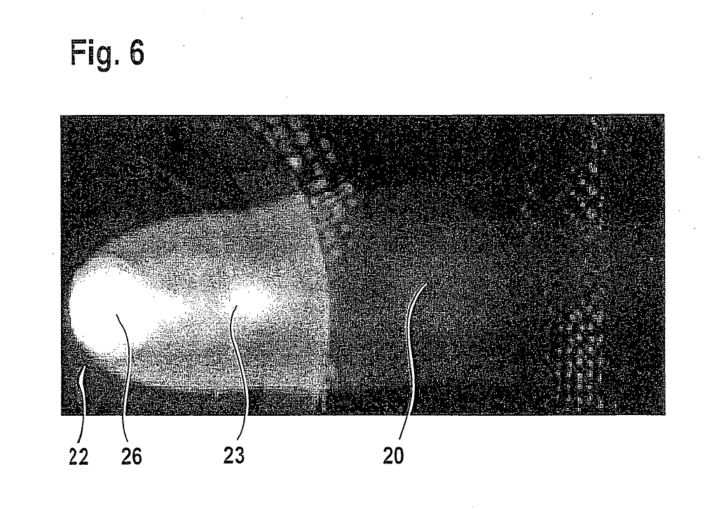

The acceleration and expansion of plasma jet 20 in the operating mode according to FIG. 4 is explained in greater detail with the help of FIG. 6, which illustrates the discharge of such an accelerated plasma jet 20 out of outlet orifice 26 into chamber 40. In particular, compression nodes 23 (Mach nodes) are clearly discernible there, indicating that plasma jet 20 is emerging from outlet orifice 26 at the velocity of sound, and thus the particles contained in plasma jet 20 at substrate 19 are at least partially accelerated to a velocity comparable to or even greater than the velocity of sound in plasma jet 20.

The marked pressure gradient between plasma jet source 5 and chamber 40, which aspirates the ionized gas present in plasma 21, i.e., plasma jet 20, into chamber 40 at a high velocity, also achieves the result that the two regions 30, 33 are largely separated with respect to the pressures prevailing there via outlet orifice 26.

The respective pressures are preferably selected so that the ratio of the pressure in first pressure range 30 to the pressure in second pressure area 33 is greater than 1.5, in particular greater than 3. For example, a pressure difference of more than 100 mbar between plasma generating space 27 in the interior of plasma jet source 5 and the interior of chamber 40 is maintained via a pumping device (not shown) which is connected to chamber 40.

On the whole, the acceleration and expansion of plasma jet 20 according to FIG. 4 have the advantage that even complex geometries of substrate 19 may be provided with coatings with no problem, and the larger cross-sectional area of plasma jet 20 at substrate 19 results in a shortened coating time and at the same time an improved homogeneity in the coating of substrate 19.

Mount 32 according to FIG. 4 is also used to introduce substrate 19 into plasma jet 20, so that plasma flows around it and works the surfaces of substrate 19, which are provided with or coated with the desired functional layer. Due to the high velocity of the reactive particles in plasma jet 20, not only do deeper cavities in the substrate 19 come in contact with plasma 21 but also the diffusion boundary layer between substrate 19 and plasma 21 is reduced, which facilitates diffusion of reactive plasma constituents onto the surface of substrate 19 and thus shortens the duration of the treatment of substrate 19 with plasma jet 20.

FIG. 5 illustrates another embodiment of a plasma system having a plasma jet source 5. In addition to FIG. 4, substrate 19 here is placed on a substrate electrode 18 which is connected to a substrate generator 37 by a generator feeder line 36 so that substrate 19 may be acted upon by an electric voltage. Due to the electric power, i.e., voltage thus injected into substrate electrode 18, ions in plasma 21, i.e., plasma jet 20 are accelerated toward substrate 19, where they impinge with an increased energy. Moreover FIG. 5 shows a conventional insulation 34 for electric separation of mount 32 and cooling water inlet 31 from substrate electrode 18. For effective movement of substrate 19 with respect to plasma jet 20 in particular during production of the functional layer, mount 32 of substrate 19 is also preferably designed to be rotatable and movable in all three directions in space.

In particular, substrate generator 37 applies an electric voltage of typically 10 V to 5 kV, in particular 5 V to 300 V, at a frequency of 0 Hz to 500 MHz, in particular 1 kHz to 50 kHz to substrate electrode 18. In a preferred variant of the exemplary embodiment according to FIG. 5, the voltage generated by substrate generator 37 is also varied, preferably pulsed, with plasma jet source 5 in a manner that correlates in time with the variation in intensity of plasma jet 21, in particular in phase opposition.

Variants of the exemplary embodiment according to FIG. 5 provide for expedient variations in the form of the electric voltage injected into substrate electrode 18, these variations being adapted to the individual case. To do so, their amplitude, frequency and/or edge steepness may be varied, an offset of a positive or negative direct voltage may be used or the voltage may be pulsed. In addition, it is not obligatory but merely advantageous if the electric voltage is varied periodically.

With regard to the pressures in first pressure area 30 and second pressure area 33 according to FIG. 5, it is advantageous if a pressure of more than 1 mbar, in particular 50 mbar to 1 bar, prevails inside plasma jet source 5, whereas a much lower pressure of less than 50 mbar, in particular 1 mbar to 10 mbar is maintained in chamber 40. This pressure ensures that an adequate mean free path length of the ions from plasma 21 prevails in chamber 40, so that the electric voltage applied to substrate electrode 18 does not result in a perceptible effect, i.e., an acceleration of the ions present in plasma jet 20 toward substrate 19. To this extent, this exemplary embodiment according to FIG. 5 operates in chamber 40 with a much lower pressure than the pressure generally used in producing coatings with the help of inductively coupled HF plasma jet sources. In this way, by using the plasma system according to FIG. 5, it is readily possible to produce coatings on substrate 19 which may otherwise be produced only by CVD processes, in particular DLC (“diamond-like carbon”) layers.

On the whole, a great variety of coatings may be produced on substrate materials which are of industrial relevance with the help of the exemplary embodiments described above, and substrates 19 may be either electrically conducting or electrically insulating. In particular, hard carbon layers may be produced in a low vacuum with the help of the above-mentioned plasma system and the method described here. In addition, the plasma system described here may also be used for treating the surface of substrate 19, e.g., for carbonizing, nitriding or heating it.

With regard to materials that may be introduced into plasma jet source 5 for deposition of a coating on substrate 19 within the context of the preceding examples, reference is first made to German Published Patent Application No. 199 58 474. In particular, at least one gaseous or microscale or nanoscale precursor material, a suspension of such a precursor material, or a reactive gas is supplied to plasma 21 in chamber 40 through inlet 10, which is designed as an injector, in plasma jet source 5 and/or plasma jet 20 through a feeder device (not shown here), so that it forms the functional coating in a modified form on substrate 19 or is integrated into it, in particular after undergoing a chemical reaction or a chemical activation. In addition, a carrier gas for the precursor material, in particular argon and/or a reactive gas for a chemical reaction with the precursor material, in particular oxygen, nitrogen, ammonia, a silane, acetylene, methane or hydrogen may be supplied to plasma 21 in plasma jet source 5, i.e., through the feeder device also located in chamber 40.

The precursor material is preferably an organic, organosilicon or organometallic compound which is supplied to plasma 21 and/or plasma jet 20 in a gaseous or liquid form, as microscale or nanoscale powder particles, as a liquid suspension, in particular having microscale or nanoscale particles suspended in it, or as a mixture of gaseous or liquid substances containing solids. In this way, a layer or a sequence of layers containing a metal silicide, a metal carbide, a silicon carbide, a metal oxide, a silicon oxide, a metal nitride, a silicon nitride, a metal boride, a metal sulfide, amorphous carbon, diamond-like carbon or a mixture of these materials may be produced as a functional coating on substrate 19 by using the plasma system explained here and the method explained here.

In conclusion, it should also be pointed out that HF generator 16 is preferably a tetrode generator, which makes is possible to generate plasma jet 20 with intensity modulation in a particularly simple manner as described here, so that the resulting temperature of substrate 19 is determined essentially by the average power of plasma jet 20 due to this intensity modulation. Thus, the method according to the present invention also makes it possible to use very high powers of plasma jet 20 for short periods of time without creating a thermal overload on substrate 19.

Furthermore, it is also possible for the regulation of the gases supplied to plasma jet source 5, e.g., central gas 12, injector gas 11 or enveloping gas 13 to correlate with the modulation of intensity of plasma jet 20 over time and/or the variation in the electric voltage applied to substrate electrode 18 over time.

1-17. (canceled)

18. A plasma system, comprising:
at least one inductively coupled high-frequency plasma jet source, including:
a burner body delimiting a plasma generating space and including an outlet orifice for a plasma jet and at least one inlet orifice for supplying at least one of a gas and a precursor material into the plasma generating space,
a coil surrounding the plasma generating space in some areas, and
a high-frequency generator connected to the coil for igniting a plasma and for injecting an electric power into the plasma; and
an electric component for periodically varying an intensity of the plasma jet over time.

19. The plasma system as recited in claim 18, wherein:
the electric component is one of:
integrated into the high-frequency generator, and
connected between the coil and the high-frequency generator.

20. The plasma system as recited in claim 18, wherein:
the burner body is designed in the form of a pot,
the coil one of surrounds the burner body in the vicinity of the outlet orifice and is integrated into the burner body,
an injector gas is supplied through the at least one inlet orifice into the plasma generating space, and
at least one second inlet is provided for at least one of supplying a central gas that reacts with an injector gas into the plasma generating space and supplying an enveloping gas that separates the burner body from the plasma produced therein in at least some areas.

21. The plasma system as recited in claim 18, wherein:
the precursor material produces a functional coating on a substrate using the plasma jet.

22. The plasma system as recited in claim 20, wherein:
the enveloping gas separates the burner body from the plasma concentrically around the plasma.

23. The plasma system as recited in claim 18, further comprising:
a chamber that communicates with the plasma jet source via the outlet orifice;
a substrate that is exposed to the plasma jet and is placeable in the chamber;
a substrate generator; and
a substrate electrode that is electrically connected to the substrate generator and on which the substrate is placed.

24. The plasma system as recited in claim 23, further comprising:
a feeder device provided in the chamber for supplying at least one of a reactive gas and the precursor material to the plasma jet.

25. The plasma system as recited in claim 24, wherein:
the feeder device includes one of an injector and a gas spray.

26. A method of producing a functional coating on a substrate placed in a chamber, comprising:
causing a high-frequency inductively coupled plasma jet source to produce a plasma having reactive particles;
causing the plasma entering through an outlet orifice as a plasma jet from the plasma jet source into the chamber connected thereto to act on the substrate so that the functional coating is one of produced and deposited on the substrate; and
periodically varying an intensity of the plasma jet on the substrate over time.

27. The method as recited in claim 26, wherein:
the intensity of the plasma jet is varied at a frequency of 1 Hz to 10 kHz.

28. The method as recited in claim 26, wherein:
the intensity of the plasma jet is varied at a frequency of 50 Hz to 1 kHz.

29. The method as recited in claim 26, wherein:
the intensity of the plasma jet is varied between an adjustable upper limit and an adjustable lower limit.

30. The method as recited in claim 26, wherein:
the intensity of the plasma jet is periodically extinguished for an adjustable period of time.

31. The method as recited in claim 26, further comprising:
injecting an electric power of 500 watt to 50 kW into the plasma via a coil at a high frequency of 0.5 MHz to 20 MHz.

32. The method as recited in claim 26, further comprising:
injecting an electric power of 1 kW to 10 kW into the plasma via a coil at a high frequency of 0.5 MHz to 20 MHz.

33. The method as recited in claim 26, further comprising:
discharging the plasma as a jet out of the plasma jet source; and
introducing the plasma into the chamber by supplying a gas at a gas flow rate of 5,000 sccm to 100,000 sccm to the plasma jet source through the outlet orifice.

34. The method as recited in claim 33, wherein:
the gas includes argon, and
the gas flow rate is 20,000 sccm to 70,000 sccm.

35. The method as recited in claim 26, further comprising:
supplying one of at least one precursor material, a suspension of the at least one precursor material, and a reactive gas to at least one of the plasma through an inlet in the plasma jet source and the plasma jet through a feeder device located in the chamber.

36. The method as recited in claim 35, wherein:
the at least precursor material includes one of a gaseous material, a microscale material, and a nanoscale material.

37. The method as recited in claim 35, wherein:
the at least one precursor material forms the functional coating on the substrate after undergoing one of a chemical reaction and a chemical activation.

38. The method as recited in claim 35, wherein:
the at least one precursor material is integrated into the substrate.

39. The method as recited in claim 26, further comprising:
supplying to the plasma at least one of a carrier gas for a precursor material and a reactive gas for a chemical reaction with the precursor material.

40. The method according to claim 39, wherein:
the carrier gas includes argon, and
the reactive gas includes one of oxygen, nitrogen, ammonia, silane, acetylene, methane, and hydrogen.

41. The method as recited in claim 39, wherein:
the precursor material includes one of an organic compound, an organosilicon compound, and an organometallic compound that is supplied to at least one of the plasma and the plasma jet in one of a gaseous form, a vapor form, and a liquid form as one of microscale powder particles, nanoscale powder particles, a liquid suspension in which is suspended one of microscale particles and nanoscale particles, and a mixture of one of gaseous and liquid substances with solids.

42. The method as recited in claim 26, wherein:
a pressure gradient is produced at least intermittently between an interior of the chamber and a plasma generating space, causing acceleration of particles contained in the plasma jet onto the substrate.

43. The method as recited in claim 26, wherein:
the plasma jet source is operated at a pressure of 1 mbar to 2 bar in an interior thereof, and
a pressure in an interior of the chamber is kept below 50 mbar.

44. The method as recited in claim 26, wherein:
the plasma jet source is operated at a pressure of 50 mbar to 1 bar in an interior thereof, and
a pressure in an interior of the chamber is kept between 1 mbar and 10 mbar.

45. The method as recited in claim 26, wherein:
the substrate is arranged on a substrate electrode that is acted upon by an electric voltage of 10 V to 5 kV at a frequency of 0 to 50 MHz.

46. The method according to claim 26, wherein:
the substrate is arranged on a substrate electrode which is acted upon by an electric voltage of 50 V to 300 V at a frequency of 1 kHz to 100 kHz.

47. The method as recited in claim 45, wherein:
the voltage is one of pulsed in phase opposition and varied over time in correlation with a change in the intensity of the plasma jet.
